(19) United States
(12) Patent Application Publication
(10) Pub. No.: US 2026/0066245 A1
(43) Pub. Date: Mar. 5, 2026

(54) Atomic Layer Process Chamber for Optimal Etching and Deposition with Controlled Ion and Radical Exposure

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/826,169

(22) Filed: Sep. 5, 2024

(51) Int. Cl. H01J 37/32; C23C 16/02; C23C 16/44; C23C 16/455; C23C 16/505; C23C 16/52; C23C 16/56; C23F 4/00; H01L 21/67

(52) U.S. Cl. CPC H01J 37/32899; C23C 16/0245; C23C 16/4408; C23C 16/45536; C23C 16/45544; C23C 16/505; C23C 16/52; C23C 16/56; C23F 4/00; H01J 37/32091; H01J 37/321; H01J 37/32422; H01J 37/3244; H01J 2237/0473; H01J 2237/332; H01J 2237/3341

(57) ABSTRACT

A plasma process chamber, divided into upper and lower sections by a grounded ion filter (GIF), is designed to optimize both ALE and ALD processes. In the ALE process, the substrate in the lower chamber is modified by chemically active neutrals, while ions are blocked by the GIF, enhancing process precision and ideality. During the ALD process, the plasma activation step utilizes radicals without ion interference, improving film conformity, particularly on high aspect ratio structures. This integrated chamber design ensures precise control and optimal conditions for both ALE and ALD, facilitating advanced semiconductor fabrication.

### BACKGROUND OF THE INVENTION

### 1. Field of Invention

The present invention generally relates to semiconductor manufacturing. More specifically, the invention pertains to a method and apparatus for enhancing atomic layer etching (ALE) and atomic layer deposition (ALD) processes within a single process chamber.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{υ {E}_{i} {J}_{i}}{1 + ( υ {E}_{i} {J}_{i} ) {/}_{( {υ}_{n} {sJ}_{n )}}} , \qquad [ 2 ]$$

where υ represents the volume removed per unit bombardment energy for a saturated surface (cm³/eV), Eᵢ the ion energy (eV), Jᵢ the ion flux to the surface (cm²/s), υₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of Inductive Coupled Plasma (ICP) or Transformer Coupled Plasma (TCP). Additionally, gas injection techniques have improved, incorporating multiple injection points to ensure a uniform plasma within the vacuum reactor, as described in U.S. Pat. No. 8,231,799 to Bera et al. and U.S. Pat. No. 10,825,659 to Treadwell. Further enhancements include optimizing the electrostatic chuck (ESC) to feature multiple zones with independently adjustable temperatures (U.S. Pat. No. 9,713,200 to Pease and U.S. Pat. No. 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and U.S. Pat. No. 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for Critical Dimension (CD), loading, and profile remains a significant challenge, often entailing considerable expense.

Plasma enhanced ALE (simply as ALE throughout this disclosure) has been developed to address the limitations of RIE. ALE apparatus has evolved from the RIE apparatus with less stringent requirements for achieving uniformity on a 300 mm wafer. However, ALE has unique requirements due to the nature of its process steps, detailed herein.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE or plasma enhanced ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process—characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \% , \qquad [ 2 ]$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus, it may increase the cost of the process.

Another solution to this problem, as disclosed in U.S. Pat. No. 10,014,192 to Singh, involves using a chamber that is divided into a plasma-generating region and a substrate-processing region by a separating plate structure. This plate structure blocks ions from reaching the substrate while utilizing low-energy metastable species to etch the substrate. However, due to the complete elimination of high-energy ions in the processing region, Singh's method is ineffective for etching high aspect ratio (HAR) structures. In such structures, high-energy ions are essential for reaching the bottom of deep or narrow features. Without sufficient ion energy, the etching process lacks the directional control needed to effectively etch HAR features.

The present invention addresses this limitation by introducing an improved chamber design that eliminates ions during the surface modification step of the ALE process but allows high-energy ions to be generated near the substrate during the sputtering step. These ions are then used for precisely etching HAR structures. This method provides greater control over the etching process, improving both the quality and consistency of the resulting semiconductor devices. This novel approach represents a significant advancement in semiconductor fabrication, supporting the production of smaller, more complex, and higher-performing electronic devices.

It should also be noted that a deposition component is often introduced in the ALE process to enhance performance, especially for controlling the profile of structures being etched. This is particularly important for high aspect ratio structures. For example, selective deposition on carbon-containing materials can improve ALE performance, as described in U.S. Pat. Pub. No. 2017/0316935 to Tan et al.

ALD processes, on the other hand, can struggle to achieve uniform deposition on high aspect ratio structures. The ions in the plasma, which activate the precursor, may exhibit an energy and angular distribution dependent on the aspect ratio, leading to non-uniform deposition and reduced film conformity.

Additionally, separating ALE and ALD processes into different chambers introduces inefficiencies in the overall fabrication process. Transferring substrates between chambers increases complexity, introduces additional process steps, and raises the risk of contamination.

As disclosed in U.S. Pat. No. 9,805,941 to Karanik et al., both ALE and ALD processes can be conducted in a single plasma chamber by alternating between the two. This method improves selectivity and prevents feature degradation during etching, but it does not fully address the challenges of conformal ALD deposition on high aspect ratio structures. or the need for ion-free surface modification steps of the ALE.

Therefore, there is a need for an improved system and method that overcomes these challenges, ensuring more effective ALE processes, improving ALD layer conformity on high aspect ratio structures, and enhancing overall efficiency in semiconductor manufacturing.

### SUMMARY

The present invention provides a system and method for enhancing ALE and ALD processes in semiconductor manufacturing. In some embodiments, both ALE and ALD are conducted within a single process chamber, improving efficiency and reducing complexity.

The process chamber is divided into an upper chamber and a lower chamber, separated by a grounded ion filter (GIF). The upper chamber contains a plasma source and operates as an inductively coupled plasma (ICP) reactor. The upper chamber includes a first gas/precursor distribution unit, which introduces gas or precursor into the upper chamber, where radicals (highly reactive neutrals) are generated. These radicals diffuse through the GIF into the lower chamber, while ions are blocked, ensuring that the substrate in the lower chamber is modified without ion bombardment during the ALE surface modification step.

The lower chamber, where the substrate is held on a chuck, is equipped with a second gas/precursor distribution unit, which can optionally introduce gas or precursor directly into the lower chamber. During the ALE sputtering step, the lower chamber operates as a capacitively coupled plasma (CCP) reactor, where the bias unit generates high-energy ions. These ions are essential for etching high aspect ratio (HAR) structures, as they penetrate deep into narrow features to achieve precise etching. The flexible design of the second gas/precursor distribution unit allows for the optional introduction of gas or precursor directly into the lower chamber when necessary, providing additional process control.

For ALD, the upper chamber again generates neutrals during the plasma activation step, while the lower chamber remains free from ion bombardment. The second gas/precursor distribution unit can optionally deliver precursors directly to the substrate in the lower chamber, where they adsorb onto the surface in the dosing step. The radicals generated in the upper chamber then diffuse into the lower chamber, reacting with the precursors to achieve uniform layer deposition in the plasma activation step. This neutral-driven activation enhances the aspect ratio conformity of the deposited layers, which is crucial for HAR structures.

The invention incorporates advanced gas/precursor delivery systems to optimize efficiency in both ALE and ALD processes. The first gas/precursor distribution unit in the upper chamber and the optional second gas/precursor distribution unit in the lower chamber work together to ensure precise delivery of gases or precursors, improving etching and deposition performance.

Additionally, the lower chamber contains a bias unit that generates capacitively coupled plasma in the lower chamber. Additionally, a tailored waveform generator maybe used for precisely controlling ion energy distribution during the sputtering step. This is crucial for high aspect ratio structure etching, ensuring that the ion energy is tuned to prevent over-etching and protect sensitive layers.

In summary, the present invention offers an integrated solution for ALE and ALD processes within a single chamber, utilizing distinct roles for the upper and lower chambers. The upper chamber generates radicals, while the lower chamber is responsible for substrate processing and high-energy ion generation for HAR etching. The optional introduction of gas or precursor into the lower chamber via the second gas/precursor distribution unit allows for enhanced process flexibility. This design improves efficiency, precision, and control in ALE and ALD processes, particularly for high aspect ratio structures.

### BRIEF DESCRIPTIONS OF THE DRAWINGS

In order to provide enhanced clarity, the following description references the accompanying drawings:

FIG. 1A illustrates an exemplary chamber partitioned into an upper chamber and a lower chamber by a GIF.

FIG. 1B presents a top-view depiction of the GIF.

FIG. 1C provides a detailed view of an exemplary design for the GIF.

FIG. 2 depicts various alternative embodiments and designs of the GIF.

FIG. 3A illustrates the three distinct operating modes of the chamber.

FIG. 3B highlights the functionalities of the upper and lower chambers during an ALE process.

FIG. 3C highlights the functionalities of the upper and lower chambers during an ALD process.

FIG. 4A showcases a first implementation for introducing gas/precursor into the lower chamber.

FIG. 4B showcases a second implementation for introducing gas/precursor into the lower chamber.

FIG. 4C showcases a third implementation for introducing gas/precursor into the lower chamber.

FIG. 4D showcases a fourth implementation for introducing gas/precursor into the lower chamber.

FIG. 5A illustrates a step-by-step flowchart describing the operations of the chamber in the first operating mode.

FIG. 5B illustrates a step-by-step flowchart describing the operations of the chamber in the second operating mode.

FIG. 5C illustrates a step-by-step flowchart describing the operations of the chamber in the third operating mode.

### DETAILED DESCRIPTIONS

To ensure comprehensive understanding, this section delves into detailed embodiments of the present invention. Although specific examples are provided for clarity, modifications and variations that align with the claims are appropriate. Conventional methods and components are highlighted to underscore the distinct features of the invention.

Terms used in this disclosure are defined as follows:
Aspect Ratio: Represents the ratio of the height to the width of a feature on a semiconductor wafer, critical in defining the geometry and performance of microstructures.
Bias Unit: Refers to a component that generates a plasma or a controlled voltage to accelerate ions towards the wafer held by an electrostatic chuck (ESC). This voltage creates an electric field that enhances ion bombardment, crucial for precise control of ion energy and directionality in processes like etching.
Chamber: An enclosed environment within process equipment where semiconductor manufacturing processes, such as etching or deposition, occur.
Chuck: A component in semiconductor manufacturing equipment that holds and secures the wafer in place during processing.
Electrostatic chuck (ESC): A type of chuck that uses electrostatic forces to hold the wafer in place during semiconductor manufacturing processes, providing uniform clamping and stability.
Gas/Precursor Distribution Unit: A component in a vacuum process chamber designed to introduce and distribute process gases or precursors uniformly across a substrate. For example, an injector can be positioned either centrally or at specific points or angles, allowing for controlled gas/precursor delivery to targeted areas. A showerhead, typically featuring a perforated plate, disperses gas evenly across the substrate, ensuring consistent exposure during processes like ALE and ALD. Additionally, a side injection mechanism introduces gas from the chamber's sides, promoting lateral flow and even distribution.
Gas/Precursor Source: The origin or supply point of process gases and precursors used in a vacuum process chamber, typically connected to a facility's centralized gas distribution system for the gases. For instance, a gas box regulates and controls the flow of specific gases, delivering them under controlled pressure and flow conditions into the process chamber, ensuring appropriate gas composition and purity for the desired process. For precursor a vaporized unit is typically employed.
Grounded Ion Filter (GIF): A conductive plate positioned parallel to the substrate to divide a vacuum chamber into an upper chamber and a lower chamber. It is designed with openings that allow neutrals to pass through and react with a substrate placed on a chuck while blocking ions. During the sputtering step of an ALE process, the GIF serves as the grounded plate of the capacitor.
High Aspect Ratio: Refers to features on a semiconductor wafer with a significantly greater height compared to their width, often challenging to manufacture due to difficulties in achieving uniformity and precision.
Lower Chamber: The lower portion of a vacuum chamber, which operates as a CCP reactor during the sputtering step of an ALE process. It operates as a thermal reactor during the dosing step of an ALD process.
Plasma Enhanced ALE (or simply ALE): An etching process used in semiconductor manufacturing that removes material layer by layer at the atomic scale, offering high control over etch depth and profile. ALE operates in cycles, each consisting of a surface modification step and a sputtering step. The surface modification step involves chemically altering the surface of the material to form a reactive layer, which is subsequently removed by physical ion bombardment during the sputtering step, ensuring high precision and selectivity in etching.
Plasma Enhanced ALD (or simply ALD): A technique that employs plasma to enhance chemical reactions on the substrate surface during film deposition. The ALD process typically involves a dosing step, where the substrate is exposed to one or more precursors, and a plasma activation step, where a reactive gas generates species like radicals. These radicals accelerate reaction kinetics, allowing for lower deposition temperatures and improved film properties, including higher density and better conformality. ALD is particularly advantageous for depositing high-quality thin films on temperature-sensitive substrates and in applications requiring precise control over film characteristics.
Plasma Process Chamber: A specialized type of vacuum chamber designed for processes involving plasma, a highly ionized gas. In semiconductor manufacturing, these chambers are used for etching and deposition, where plasma provides the energy needed to activate chemical reactions or remove material from the wafer surface.
Plasma Source: A device that generates plasma for use in semiconductor manufacturing processes like etching, deposition, and surface modification. Common types include inductively coupled plasma (ICP), transformer coupled plasma (TCP), and capacitively coupled plasma (CCP). ICP uses an RF magnetic field from a coil to produce plasma. TCP employs a planar coil and RF energy to create plasma through transformer action. CCP generates plasma by applying RF power across two electrodes, creating an electric field that ionizes the gas.
Process System: The integrated equipment and machinery used in semiconductor manufacturing to carry out various processes such as deposition, etching, and cleaning.
Reactive Ion Etching (RIE): A plasma-based etching technique used in semiconductor manufacturing where both physical ion bombardment and chemical reactions work synergistically to remove material from a substrate. In RIE, a reactive gas is ionized in plasma, creating a mix of ions and neutral species. The ions are accelerated toward the substrate by an electric field, physically sputtering material, while the chemically reactive neutrals enhance etching.
Resonator: A device or circuit component designed to resonate at a specific radio frequency, crucial for applications like RF impedance matching in RF circuits. Resonators can be constructed using various technologies like LC circuits (inductor-capacitor circuits) and are used to provide high selectivity and stability at their resonant frequency.
RF Power Generator: A device that generates radio frequency power used in semiconductor manufacturing processes to energize plasma for etching or deposition.
Sheath: In plasma, the boundary layer between the plasma and a surface, where a strong electric field forms. This region controls the energy and flux of ions and electrons reaching the surface, crucially influencing processes like etching and deposition in semiconductor manufacturing.
Substrate: The base material, typically a silicon wafer, upon which semiconductor devices are fabricated.
System Controller: The central unit that manages and controls the various operations and parameters of semiconductor manufacturing process systems, ensuring coordinated and efficient functioning.
Tailored Waveform Generator: A device that produces custom-designed electrical waveforms to optimize plasma processes in semiconductor manufacturing. By adjusting the shape, frequency, and amplitude of the waveforms, it allows precise control over plasma characteristics, enhancing etching and deposition performance, uniformity, and selectivity.
Transmission Line (in RF): A specialized conductor or set of conductors designed to carry radio frequency (RF) signals with minimal loss and distortion. In semiconductor manufacturing, transmission lines efficiently transfer RF power from the generator to the plasma source or other RF components. They ensure impedance matching to minimize reflections and power losses, enabling precise and reliable delivery of RF energy for processes like etching and deposition.
Upper Chamber: The upper portion of a vacuum chamber separated by a GIF. It operates as an ICP reactor during the surface modification step of an ALE process and the plasma activation step of an ALD process.
Vacuum Chamber: An enclosed space from which air and other gases are removed to create a low-pressure environment. Used in semiconductor manufacturing to conduct processes requiring controlled atmospheric conditions, such as deposition and etching, to prevent contamination and ensure precision.
Window: In a vacuum chamber, this is a non-conductive, transparent or semi-transparent barrier that separates the plasma generation region from external components while allowing electromagnetic waves, such as RF or microwave energy, to pass through.

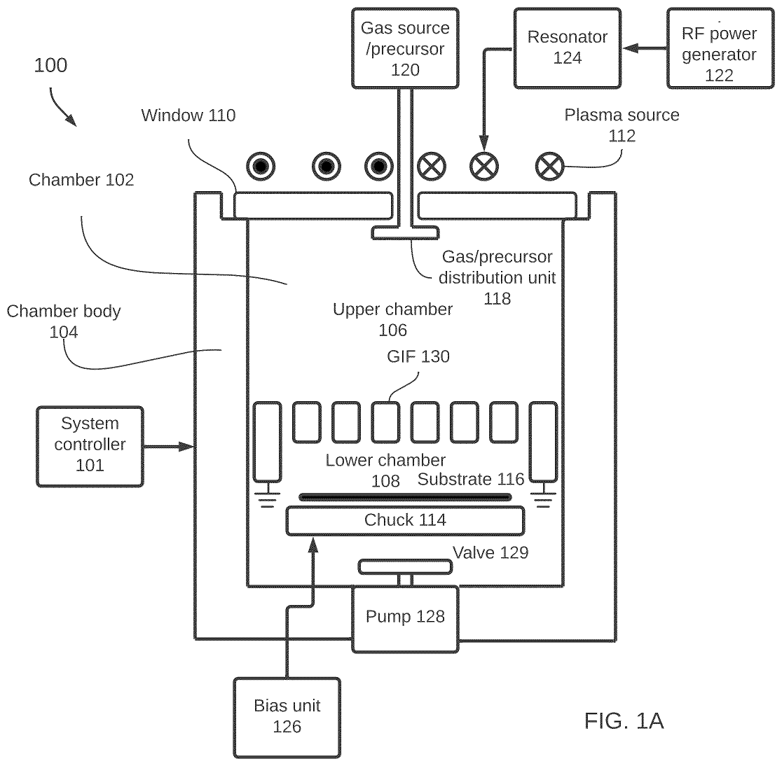

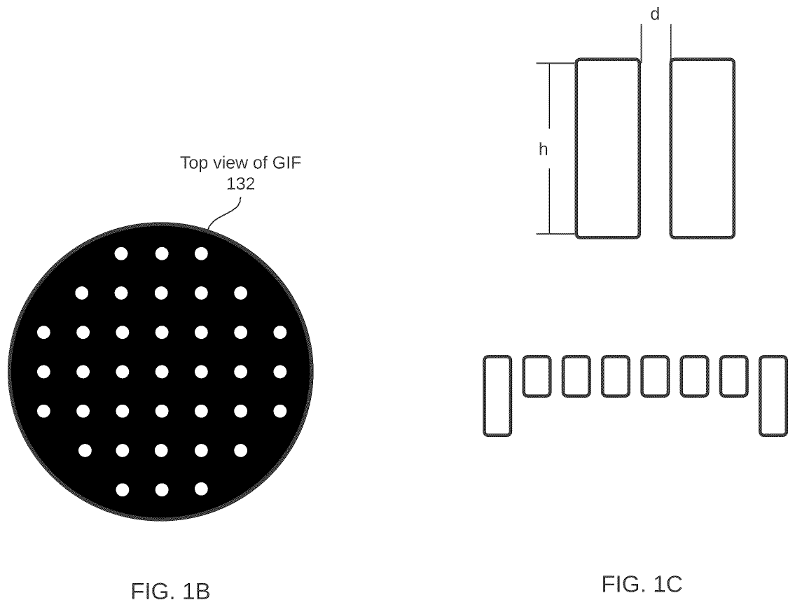

FIG. 1A illustrates an exemplary semiconductor process system, designated as 100, which incorporates a plasma process chamber, identified as 102. The operations within the chamber 102 are controlled by a system controller, denoted as 101. The chamber 102 is enclosed by a chamber body, referenced as 104, creating a vacuum environment suitable for plasma processing. Affixed to the top of the chamber body 104 is a window, designated as 110, which hermetically seals the chamber. In certain embodiments, the window may be made of quartz, while in other embodiments, it may be fabricated from ceramics.

Located on top of the window 110 is a plasma source, identified as 112. In FIG. 1A, the plasma source is shown as a three-turn coil; however, it is important to note that the coil can have a different number of turns, depending on specific operational requirements, and it may also consist of multiple coils. Although the illustration depicts a flat coil, coils of other configurations, such as cylindrical or conical, may be used as necessary.

The plasma source 112 is operatively connected to a radio frequency (RF) power generator, referred to as 122, via a resonator, designated as 124. The RF power generator 122 is capable of producing RF power at single or multiple frequencies, such as 100 kHz, 400 kHz, 2 MHz, 13.56 MHz, and 60 MHz. The resonator 124 ensures impedance matching between the RF power generator 122 and the plasma load in the chamber 102, accounting for the effects of transmission lines, as is common in the field.

A gas/precursor distribution unit, referred to as 118, is connected to a gas/precursor source, denoted as 120, through an aperture in the window 110. It is essential to ensure that this aperture is hermetically sealed to maintain the vacuum integrity of the chamber 102. The gas/precursor source 120 may include separate delivery systems for gases and precursors. For example, the gas delivery system may include a gas box, while the precursor delivery system could consist of a vaporized liquid precursor delivery system, a vaporized solid precursor delivery system, or a vaporizer. The gas/precursor distribution unit 118 can take the form of an injector or a showerhead, depending on the specific embodiment. In an alternative embodiment, the window 110 could also serve as a showerhead, sealing the vacuum chamber while dispersing gas. Additionally, the gas/precursor distribution unit 118 may incorporate lateral gas introduction mechanisms for more controlled delivery.

Inside the chamber 102 is a chuck, denoted as 114, which supports a substrate, referenced as 116. The chuck 114 may be an electrostatic chuck (ESC) or a vacuum chuck, among other possible configurations.

The chamber 102 is further divided into an upper chamber 106 and a lower chamber 108 by a GIF, designated as 130. The GIF 130 is made of conductive materials such as aluminum or silicon, with aluminum optionally anodized for enhanced erosion resistance. The GIF 130, positioned parallel to the substrate 116, blocks ions while allowing neutrals to pass through. Grounding of the GIF 130 can be achieved through the chamber body 104 or other grounded components like liners (not shown).

The upper chamber 106 functions as an ICP chamber, where plasma is ignited, producing electrons, ions, and neutrals. The GIF 130 serves as a barrier that blocks ions but permits neutrals to diffuse through multiple openings, as shown in FIG. 1B, which provides a top-view of the GIF 130, displaying exemplary openings 132. FIG. 1C details an opening's diameter “d” and height “h.” To effectively block ions, these openings need a small diameter and a large aspect ratio (h/d), with the height ranging from 0.1 mm to 10 mm and aspect ratios from 10 to 500.

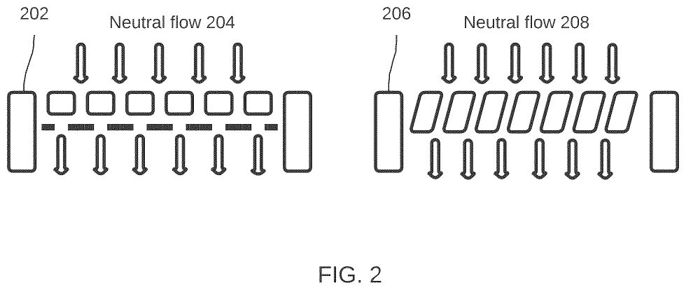

There are several possible designs for the GIF 130, as illustrated in FIG. 2. In the first example 202, the conducting paths for neutrals include a first group of vertical holes, connected to a horizontal conducting channel, which is in turn linked to a second group of vertical holes. The holes in the second group are deliberately misaligned with those in the first group, ensuring that ions are blocked while neutrals can diffuse through the GIF 130 (neutral flow 204). In the second example 206, the openings are angled relative to the vertical axis of the GIF 130, which prevents ions from passing through but allows neutral flow 208 to diffuse.

The openings in the GIF 130 are not limited to circular shapes; they may also be square, rectangular, elliptical, hexagonal, or octagonal. The size, depth, and distribution of these openings may vary, and they can be uniform or non-uniform. The GIF 130's thickness is also variable. Different techniques for blocking ions, such as multiple horizontal channels or angled openings, fall within the scope of the present invention.

Referring again to FIG. 1A, during operation, the upper chamber 106 functions as an ICP chamber. After plasma is ignited, electrons migrate toward the GIF 130 and the chamber body 104. Because the GIF 130 is grounded and does not have a blocking capacitor, the plasma sheath on its surface remains thin, extending the operational life of the GIF 130 by reducing ion bombardment.

Conversely, the lower chamber 108 operates as a CCP (capacitively coupled plasma) chamber in a sputtering step of an ALE process, where the GIF 130 acts as the grounded electrode and the chuck 114 serves as the powered electrode. In one embodiment, the chuck 114 receives RF power at a predetermined frequency from a bias unit 126, with the frequency ranging from 100 kHz to 100 MHz. In another embodiment, the bias unit 126 delivers RF power at multiple frequencies, such as 100 kHz, 400 kHz, 1 MHz, 2 MHz, 13.56 MHz, and 60 MHz. The bias unit 126 establishes a bias on the chuck 114 and can also initiate capacitively coupled plasma in the lower chamber 108 between the two electrodes. Typically, the plasma density in a CCP reactor is lower than in an ICP reactor; however, increasing the RF frequency from the bias unit 126 can enhance the plasma density in the lower chamber 108.

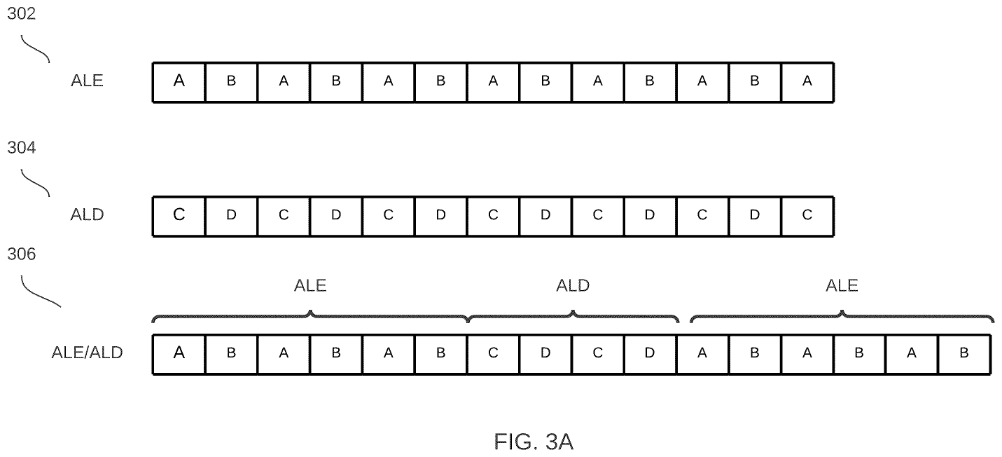

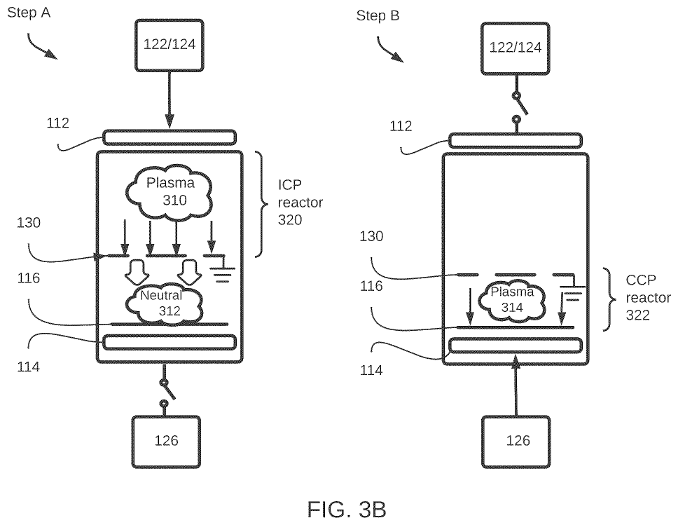

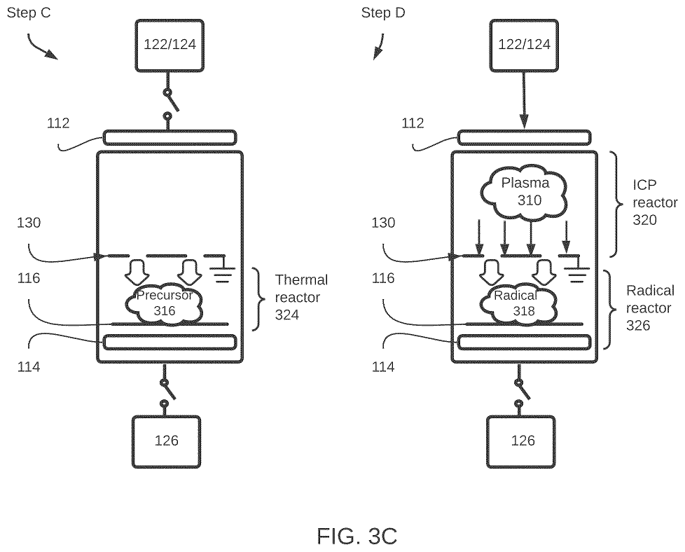

In FIG. 3A, three operating modes of the process chamber 102 are illustrated. The first mode is the ALE-only operating mode, denoted as 302. ALE is a cyclic process consisting of multiple cycles, each involving a surface modification step (A) and a sputtering step (B). Similarly, the ALD-only process 304 is also cyclic, comprising a dosing step (C) and a plasma activation step (D).

In many semiconductor manufacturing applications, ALE and ALD processes can be synergistically integrated to optimize the substrate 116. For instance, in advanced processes, an ALD process can be used to deposit a thin, conformal layer to adjust the critical dimension (CD) of an opening like a trench or a hole after an ALE process is used to etch a layer. In another scenario, especially in the formation of high aspect ratio structures, an ALD process can be used to deposit a sidewall-protecting layer after an etching step by ALE. Additionally, ALE can enhance the gap-fill capabilities in high aspect ratio openings performed by ALD.

The combined ALE and ALD process, illustrated as 306 in FIG. 3A, can result in either net deposition or net etching, depending on the application. As a result, the combined process may begin with either an ALE or ALD process and end with either process. The ALE and ALD processes within 306 are referred to as phases, and the cycle counts of the ALE and ALD phases can be adjusted according to specific application requirements.

Continuing from the above, during the sputtering step (B) of the ALE process, the bias unit 126 supplies RF power to the chuck 114, transforming the lower chamber 108 into a CCP reactor 322. In this mode, argon gas is injected into the process chamber, and an argon plasma 314 is generated in the space between the GIF 130 and the substrate 116. Positive argon ions are accelerated by the electric field created by the plasma sheath, propelling them toward the substrate 116 and removing the modified surface layer. The GIF 130, being grounded, prevents these ions from entering the upper chamber 106.

In the ALD process, steps C and D are conducted sequentially, similar to ALE. During the dosing step (C), a precursor is introduced into the lower chamber 108 and adsorbs onto the substrate's surface, forming a monolayer. This step can be followed by a gas purge to remove any excess precursor. Subsequently, during the plasma activation step (D), the substrate is exposed to radicals, which react with the precursor monolayer, resulting in the formation of a desired film on the substrate.

Overall, the innovative design of the process chamber, as illustrated in FIG. 1A, enables efficient execution of both ALE and ALD processes. The design effectively separates the upper and lower chambers, using the GIF 130 to regulate the flow of ions and neutrals, ensuring that each step of the process is conducted under optimal conditions. This separation results in precise control over film formation and etching processes on the substrate 116, ultimately leading to higher quality and more reliable semiconductor devices.

This detailed explanation demonstrates how the chamber 102 tackles the challenges faced in conventional ALE and ALD processes. By regulating the roles of the upper and lower chambers, the invention ensures that each step is executed under optimal conditions, resulting in a more precise and efficient process for film formation and etching.

For example, in the ALE process, the separation of the upper and lower chambers effectively prevents ion bombardment during the surface modification step (A), which is critical for achieving an ideal ALE process. During the sputtering step (B), the CCP reactor generates energetic ions with improved directionality, facilitating the removal of modified layers from high aspect ratio structures, thereby enhancing the precision of the ALE process.

In some implementations, the bias unit 126 produces a tailored waveform, further improving process precision. This tailored waveform enables ions with a narrowly defined energy distribution, which is crucial for the formation of high aspect ratio structures.

Additionally, during the ALD process, the chamber design ensures effective precursor delivery to the substrate surface while preventing unwanted interactions with plasma. The radical-assisted plasma activation step (D), which utilizes neutrals diffused through the GIF 130 to react with the adsorbed precursor, further enhances the conformity of the deposited ALD layer, meeting the stringent requirements of advanced semiconductor manufacturing.

Overall, this invention represents a significant advancement in semiconductor manufacturing, offering a highly efficient and precise means of executing both ALE and ALD processes, ultimately resulting in the production of higher-quality and more reliable semiconductor devices.

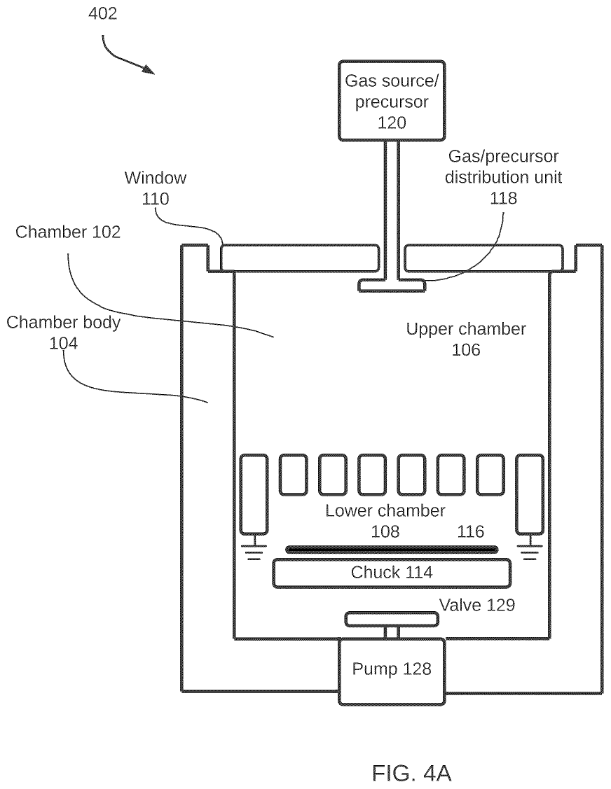

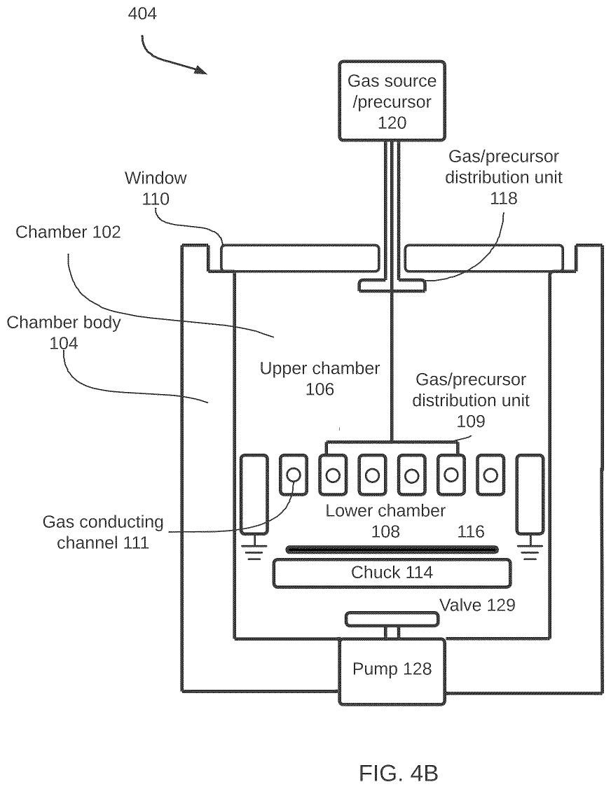

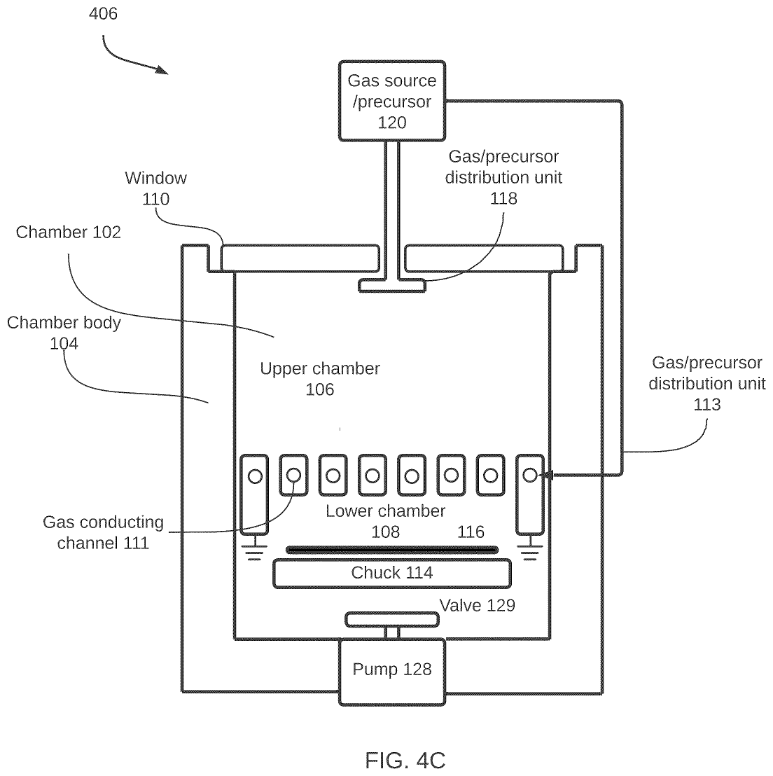

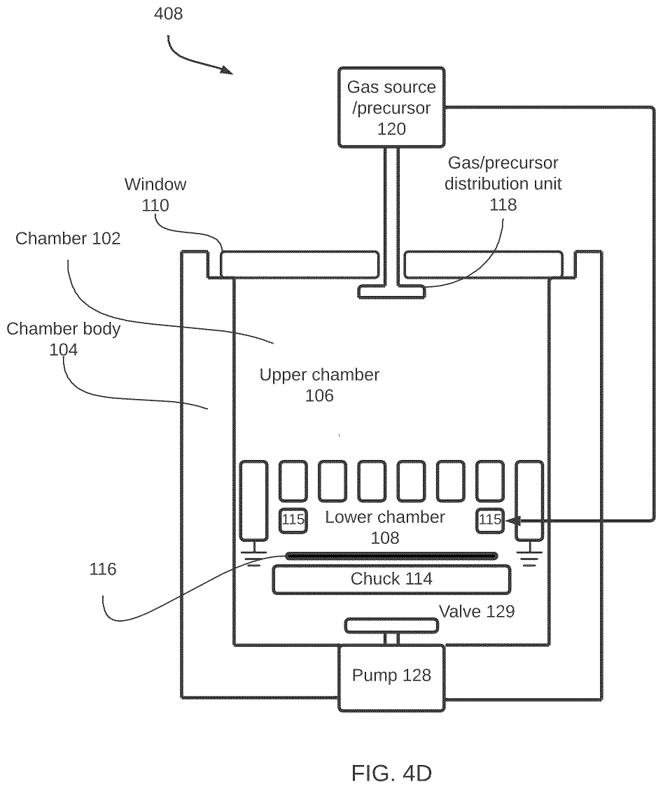

FIGS. 4A-4D present various methods for injecting argon into the lower chamber 108. In one method, argon flows from the gas/precursor source 120 into the upper chamber 106 via the first gas/precursor distribution unit 118. From there, it diffuses into the lower chamber 108 through openings in the GIF 130. Another approach uses a second gas/precursor unit 109. The GIF 130 is used as a showerhead, directing argon from the gas/precursor source 120 into the lower chamber 108. Alternatively, argon can be introduced via another implementation of the second gas/precursor delivery unit 113 situated at the side of the GIF 130, which has multiple receiving ports for even distribution. Lastly, argon can be directly injected into the lower chamber 108 via still another version of the second gas/precursor distribution unit 115 positioned below the GIF 130.

These implementations serve as illustrative examples, and many other variations and modifications can be conceived within the scope of the inventive concept.

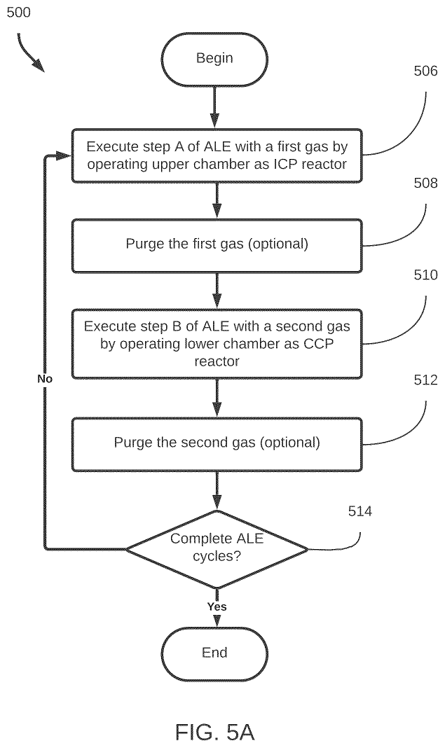

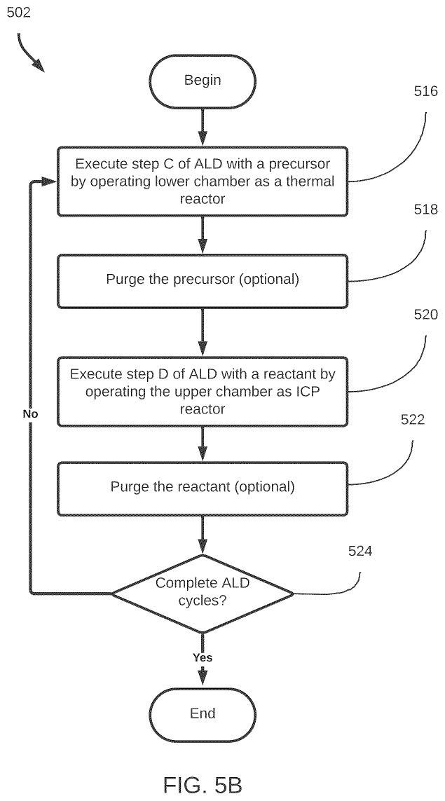

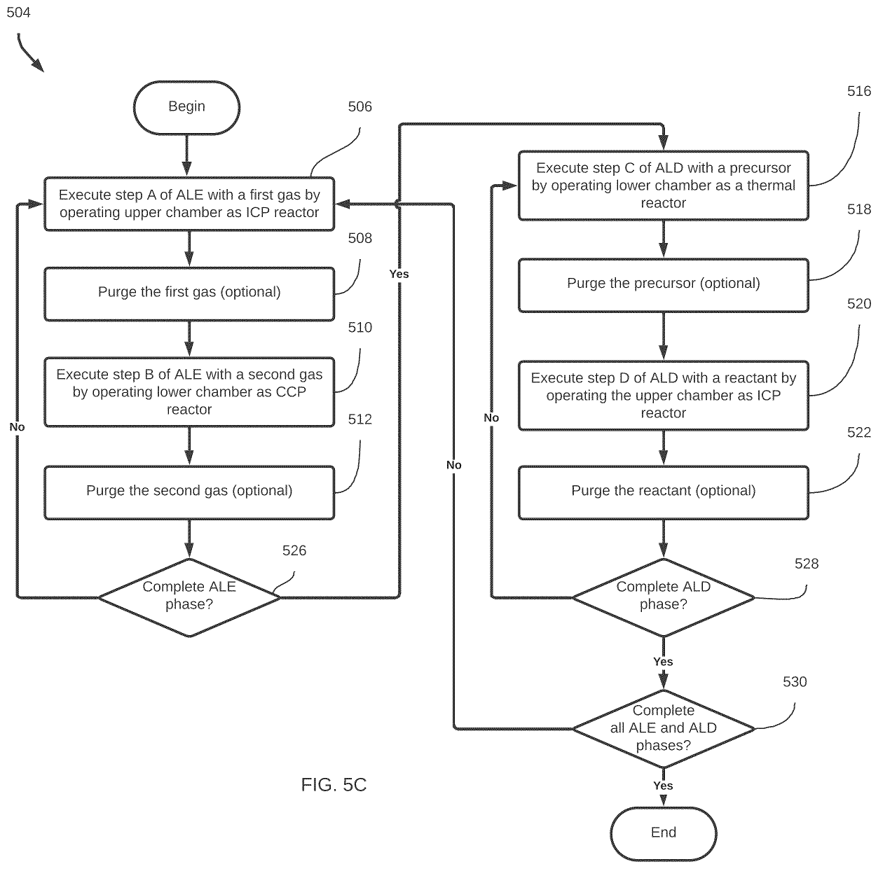

FIG. 5A details an exemplary ALE process 500. The process begins in step 506, where the system controller 101 initiates the surface modification step (A) of the ALE process by activating the plasma source 112 to receive RF power from the RF power generator 122, while simultaneously ceasing the supply of RF power to the chuck 114 from the bias unit 126. This action ignites plasma in the upper chamber 106, and the GIF 130 blocks ions but allows neutrals to flow into the lower chamber 108, where chemically active neutrals (radicals) modify the substrate 116. Optionally, in step 508, the chambers can be purged to remove residual gas or neutrals after the surface modification step, ensuring that unwanted byproducts or excess gases are cleared.

Next, in step 510, the system controller 101 initiates the sputtering step (B) by turning off the plasma source 112 and directing a second gas (e.g., argon) into the lower chamber 108, using one of the configurations from FIGS. 4A-4D. The bias unit 126 then delivers RF power to the chuck 114, which acts as the powered electrode in the CCP reactor configuration of the lower chamber 108. The RF power generates an electric field that accelerates ions toward the substrate 116, facilitating the removal of the modified layer. The plasma sheath on the substrate thickens, causing positively charged ions to accelerate, impacting the surface to etch away the modified material. In one implementation, a tailored waveform generator may be optionally added as a part of the bias unit 126 to create high energy ions with tighter energy distributions.

An optional purge step 512 may follow the sputtering step to remove any remaining etch byproducts or neutral species from the chamber. After the purge, the cycle can repeat according to the process recipe, as indicated in step 514. The ALE cycle continues in this manner, alternating between the surface modification and sputtering steps until the desired etch depth or pattern is achieved.

FIG. 5B illustrates an exemplary ALD process 502. In step 516, the dosing step (C) begins with the system controller 101 introducing a first precursor gas into the lower chamber 108 via the gas/precursor distribution unit 118. During this step, both the plasma source 112 and the bias unit 126 are turned off, allowing the lower chamber 108 to function as a thermal reactor. The precursor gas adsorbs onto the surface of the substrate 116, forming a thin, uniform monolayer.

Following the dosing step, an optional purge step 518 may be employed to remove excess precursor or unreacted gases from the lower chamber 108. This prevents unwanted reactions in the subsequent plasma activation step.

Next, in step 520, the plasma activation step (D) is conducted. The system controller 101 activates the plasma source 112, which receives RF power from the RF power generator 122 to ignite plasma in the upper chamber 106. The GIF 130 blocks ions but allows neutrals including radicals to diffuse into the lower chamber 108. These radicals react with the adsorbed precursor monolayer on the substrate 116, forming a dense, conformal film.

An additional optional purge step 522 may follow the plasma activation step to remove any byproducts generated during the reaction. The cycle then repeats according to the ALD process recipe, as shown in step 524. The ALD process continues with repeated cycles of precursor dosing and plasma activation until the desired film thickness or properties are achieved.

FIG. 5C outlines the combined ALE and ALD processes. The process begins with the ALE phase, where the system controller 101 executes steps 506-512 from the ALE process, as described in FIG. 5A. This phase may involve multiple cycles, as dictated by the process recipe, which are repeated until the desired etch depth or feature profile is obtained, as indicated in step 526.

Once the ALE phase is completed, the ALD phase follows. The system controller 101 proceeds to execute steps 516-524, as outlined in FIG. 5B, performing repeated cycles of precursor dosing and plasma activation. These ALD cycles are conducted according to the specified process recipe, as shown in step 530. The number of ALD cycles can be adjusted to achieve the required film thickness or properties.

The combined ALE and ALD process allows for the precise control of both etching and deposition, making it suitable for advanced semiconductor manufacturing processes. This integration can result in net deposition, net etching, or a combination of both, depending on the specific requirements of the application. The process can start and end with either an ALE or ALD phase, depending on the desired outcome. The cycle counts for each phase can be varied to optimize process results, as required for different device architectures.

It should also be noted that ALD and ALE processes may be conducted at different temperatures. A temperature ramping up or ramping down step may be needed between the ALE and the ALD cycles or between the ALD and the ALE cycles. Adjusting operating temperature of ESC can slow down the overall process. It is, therefore, important to design frequency of the insertion for either ALE or ALD cycles.

1. A process chamber for performing ALE and ALD processes, comprising:
an upper chamber and a lower chamber separated by a GIF;
a plasma source, connected to a first RF power generator, configured to generate an inductively coupled plasma in the upper chamber;
a bias unit comprising at least a second RF power generator, connected to a chuck, configured to generate a capacitively coupled plasma in the lower chamber;
a first gas/precursor distribution unit configured to deliver a gas or a precursor into the upper chamber;
a second gas/precursor distribution unit configured to deliver a gas or a precursor into the lower chamber;
a system controller configured to:
operate the plasma process chamber in a surface modification step of an ALE process, wherein the plasma source generates the inductively coupled plasma in the upper chamber, wherein the GIF blocks ions in the plasma from entering the lower chamber while allowing neutrals entering the lower chamber to modify the substrate surface;
operate the plasma process chamber in a sputtering step of the ALE process, wherein the bias unit generates the capacitively coupled plasma in the lower chamber, wherein the ions in the plasma are accelerated by a voltage bias caused by the bias unit to remove the modified layer;
operate the plasma process chamber in a dosing step of an ALD process, wherein a precursor is delivered into the lower chamber through either the first or the second gas/precursor delivery unit, wherein the precursor is adsorbed on the substrate surface; and
operate the plasma process chamber in a plasma activation step of the ALD process, wherein the plasma source generates the inductively coupled plasma in the upper chamber during a plasma activation step, wherein the GIF blocks ions in the plasma from entering the lower chamber while allowing neutrals entering the lower chamber to react with the precursor adsorbed on the substrate surface.

2. The chamber of claim 1, wherein a gas is introduced into the upper chamber through the first gas/precursor distribution unit during the surface modification step of the ALE process, wherein the gas further includes a halogen.

3. The chamber of claim 1, wherein an inert gas is introduced into the lower chamber through the second gas/precursor delivery unit during the sputtering step of the ALE process.

4. The chamber of claim 1, wherein a gas or a precursor is introduced into the upper chamber through the first gas/precursor delivery unit during the plasma activation step of the ALD process.

5. The chamber of claim 1, wherein the ALE process further comprises a purge step, executed by the system controller, between the surface modification and the sputtering steps, or between the sputtering and the surface modification steps.

6. The chamber of claim 1, wherein the ALD process further comprises a purge step, executed by the system controller, between the dosing and the plasma activation steps, or between the plasma activation and the dosing steps.

7. The chamber of claim 1, wherein the ALE process and the ALD process further comprises cycles, wherein the ALD cycles can be inserted into a sequence of ALE cycles, or ALE cycles can be inserted into a sequence of ALD cycles.

8. The chamber of claim 1, wherein the openings in the GIF are dimensioned and configured to minimize ion leakage through the openings.

9. The chamber of claim 1, wherein the openings in the GIF are oriented at an angle relative to the vertical direction with respect to the substrate surface.

10. The chamber of claim 1, wherein the openings in the GIF comprise a first set of openings, a horizontal conducting channel connected to the first set of openings, and a second set of openings connected to the horizontal conducting channels, wherein the openings in the second set are misaligned from the openings in the first set.

11. The chamber of claim 1, wherein the plasma source is deactivated during the sputtering step of the ALE or the dosing step of ALD.

12. The chamber of claim 1, wherein the bias unit is deactivated during the surface modification step of the ALE or the plasma activation step of ALD.

13. The chamber of claim 11, wherein the bias unit further includes a tailored waveform generator.

14. A method for processing a substrate, the method comprising:
providing a plasma process chamber, comprising an upper chamber and a lower chamber separated by a GIF, wherein the chamber further comprising a plasma source configured to generate an inductively coupled plasma in the upper chamber, a bias unit, connected to a chuck, for generating a capacitively coupled plasma in the lower chamber, a first gas/precursor delivery unit, and a second gas/precursor delivery unit;
performing by a system controller an ALE process, comprising:
operating the plasma process chamber in a surface modification step of the ALE process, wherein the plasma source generates the inductively coupled plasma in the upper chamber, wherein the GIF blocks ions from the plasma from entering the lower chamber while allowing neutrals entering the lower chamber to modify the substrate surface;
operating the plasma process chamber in a sputtering step of the ALE process, wherein the bias unit generates the capacitively coupled plasma in the lower chamber, wherein the ions in the plasma are accelerated by a voltage bias caused by the bias unit to remove the modified layer; and
performing by the system controller an ALD process, comprising:
operating the plasma process chamber in a dosing step of an ALD process, wherein a precursor is delivered into the lower chamber through the second gas/precursor delivery unit, wherein the precursor is adsorbed on the substrate surface; and
operating the plasma process chamber in a plasma activation step of the ALD process, wherein the plasma source generates the inductively coupled plasma in the upper chamber, wherein the GIF blocks ions from the plasma from entering the lower chamber while allowing neutrals entering the lower chamber to react with the precursor adsorbed on the substrate surface.

15. The method of claim 14, wherein the ALE process and the ALD process further comprises cycles, wherein the ALD cycles can be inserted into a sequence of ALE cycles, or ALE cycles can be inserted into a sequence of ALD cycles.

16. The method of claim 15, wherein the combined ALE and ALD process can be utilized to perform a gap fill process.

17. The method of claim 15, wherein the combined ALE and ALD process can be utilized to a patterning process to reduce critical dimension of a trench or a hole by forming a spacer structure.

18. A process chamber for performing ALD on a substrate, comprising:
an upper chamber and a lower chamber separated by a GIF, wherein the GIF is configured to block ions from passing from the upper chamber to the lower chamber while allowing neutrals diffusing through openings of the GIF from the upper chamber to the lower chamber;
a plasma source configured to generate an inductively coupled plasma in the upper chamber;
a first and a second gas/precursor distribution units configured to introduce gases or precursors into the upper or the lower chambers; and
a system controller configured to:
introduce a precursor, in a dosing step, into the lower chamber through the second gas/precursor delivery units, without activating the plasma source, wherein the precursor is reacted with the substrate surface;
introduce a reactant gas into the upper chamber and operate the plasma source to generate an inductively coupled plasma in the upper chamber, wherein ions in generated plasma are blocked by the GIF and neutrals from the plasma are diffused through the openings in the GIF and react with the precursor adsorbed on the substrate surface in the lower chamber.

19. The chamber of claim 18, wherein the openings in the GIF are dimensioned and configured to minimize ion leakage through the openings.

20. The chamber of claim 18, wherein the openings in the GIF are oriented at an angle relative to the vertical direction with respect to the substrate surface.
